(19) United States
(12) Patent Application Publication
(10) Pub. No.: US 2025/0253608 A1
(43) Pub. Date: Aug. 7, 2025

(54) MULTI-LAYER COMPOSITE HEAT DISSIPATION SUBSTRATE

(71) Applicant: TONG HSING ELECTRONIC INDUSTRIES, LTD., Taoyuan City (TW)

(72) Inventors: CHENG-HUNG SHEN, Taoyuan City (TW); CHUN-CHIEH LIAO, Taoyuan City (TW); JHIH-WEI LAI, Taoyuan City (TW); JIAN-YU SHIH, Taoyuan City (TW)

(21) Appl. No.: 18/895,410

(22) Filed: Sep. 25, 2024

Related U.S. Application Data
(60) Provisional application No. 63/550,155, filed on Feb. 6, 2024.

(30) Foreign Application Priority Data
Jun. 13, 2024 (TW) 113121784

(51) Int. Cl. H01S 5/02; H01S 5/024

(52) U.S. Cl. CPC H01S 5/0213; H01S 5/0216; H01S 5/02469

(57) ABSTRACT

A multi-layer composite heat dissipation substrate includes a substrate body, a first insulation layer, a first electrode layer, a second electrode layer, and a solder layer. The substrate body has a first surface and a second surface. The first insulating layer is formed on the first surface of the substrate body. The first insulating layer is made of an insulating material selected from the group consisting of: nitride, oxide, and oxynitride. The first electrode layer is formed on a top surface of the first insulating layer. The second electrode layer is located below the substrate body. The solder layer is formed on a top surface of the first electrode layer.

### CROSS-REFERENCE TO RELATED PATENT APPLICATION

This application claims the benefit of priority to Taiwan Patent Application No. 113121784, filed on Jun. 13, 2024. The entire content of the above identified application is incorporated herein by reference.

This application claims the benefit of priority to the U.S. Provisional Patent Application Ser. No. 63/550,155, filed on Feb. 6, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat dissipation substrate, and more particularly to a multi-layer composite heat dissipation substrate being used to carry a high-power chip, such as a laser chip, for heat dissipation.

### BACKGROUND OF THE DISCLOSURE

Laser chip, also known as laser diode, is mainly used in fields such as general optical fiber communications, biological sensing, and industrial sensing. When the laser chip is used, the laser chip is usually disposed on a heat dissipation substrate to form a laser light source module. The heat dissipation substrate is used to assist the laser chip in dissipating heat. An existing heat dissipation substrate includes an insulating substrate and two electrode layers, and the two electrode layers are respectively located on two side surfaces of the insulating substrate.

Due to the unsatisfactory matching of thermal expansion rates in the combination of the existing heat dissipation substrate and the laser chip, thermal stress is easily formed and heat conduction is also limited, thus the performance and the life of the high-power laser chip are easily affected.

Therefore, how to improve the overall heat dissipation effect of the heat dissipation substrate and the matching of the heat dissipation substrate and the laser chip through structural design improvements to overcome the above-mentioned defects has become an important issue to be addressed in this technological field.

### SUMMARY OF THE DISCLOSURE

In response to the above-referenced technical inadequacy, the present disclosure provides a multi-layer composite heat dissipation substrate to enhance the overall heat dissipation effect of the heat dissipation substrate.

In one aspect, the present disclosure provides a multi-layer composite heat dissipation substrate. The multi-layer composite heat dissipation substrate includes a substrate body, a first insulating layer, a first electrode layer, a second electrode layer, and a solder layer. The substrate body has a first surface and a second surface. The first insulating layer is formed on the first surface of the substrate body. The first electrode layer is formed on a top surface of the first insulating layer. The first insulating layer is located between the substrate body and the first electrode layer. The first insulating layer is made of an insulating material selected from the group consisting of nitride, oxide, and oxynitride. The second electrode layer is located below the substrate body. The solder layer is formed on a top surface of the first electrode layer.

Therefore, one of the beneficial effects of the present disclosure is that, by virtue of including the substrate body, the first insulating layer, the first electrode layer, the second electrode layer, and the solder layer, and the insulating layer being located between the substrate body and the electrode layer, the multi-layer composite heat dissipation substrate provided by the present disclosure has higher thermal conductivity compared with the thermal conductivity of the existing ceramic substrate, such that the heat dissipation effect for high-power chips is improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a multi-layer composite heat dissipation substrate according to a first embodiment of the present disclosure; and

FIG. 2 is a schematic cross-sectional view of the multi-layer composite heat dissipation substrate according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

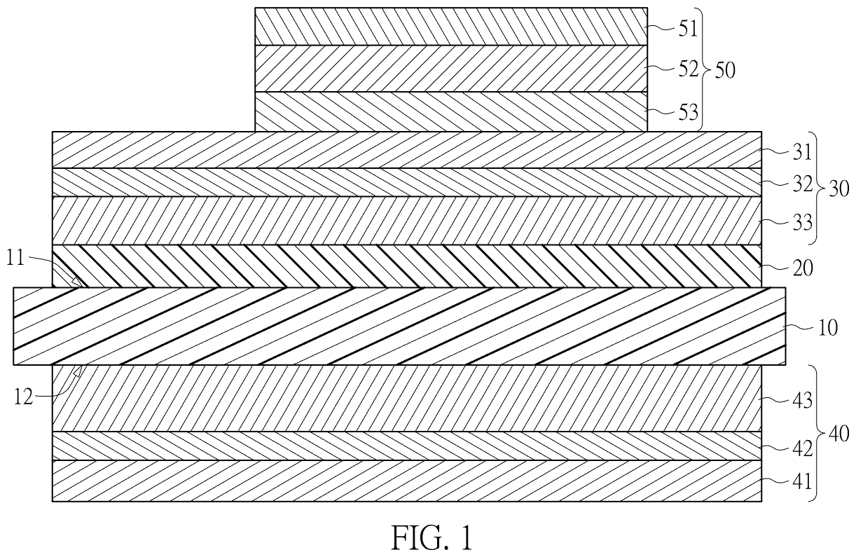

Referring to FIG. 1, the present disclosure provides a multi-layer composite heat dissipation substrate that includes a substrate body 10, a first insulating layer 20, a first electrode layer 30, a second electrode layer 40, and a solder layer 50.

The substrate body 10 has a first surface 11 and a second surface 12. In the figures of this embodiment, the first surface 11 is an upper surface of the substrate body 10, and the second surface 12 is a lower surface of the substrate body 10. The substrate body 10 may be made of electrically conductive silicon carbide such as N-type conductive silicon carbide (SiC), semi-insulating silicon carbide (SiC), ceramic, diamond, or a diamond-metal mixture, but is not limited thereto. A substrate body 10 made of diamond has higher thermal conductivity compared with a substrate body 10 made of silicon carbide (SiC) or ceramic. The substrate body 10 made of diamond-metal mixture may be, for example, a diamond substrate doped with metal, such as a copper-doped high thermal conductivity copper-based diamond composite. Therefore, the substrate body 10 made of a diamond-metal mixture has good thermal conductivity, and reduces costs compared to the substrate body 10 purely made of diamond.

The first insulating layer 20 is formed on the first surface 11 of the substrate body 10. In this embodiment, the first insulating layer 20 is made of an insulating material selected from the group consisting of nitride, oxide, and oxynitride. Specifically, the nitride may be, for example, silicon nitride (Si₃N₄) or aluminum nitride (AlN). The oxide may be, for example, silicon dioxide (SiO₂) or aluminum oxide (Al₂O₃). The oxynitride refers to a compound containing nitrogen, oxygen, and other elements, such as silicon oxynitride (SiOₓN_{y}) or aluminum oxynitride (AlON).

In this embodiment, procedures for combining the first insulating layer 20 with the substrate body 10 are illustrated below with the following examples. The first insulating layer 20 may be formed by plating nitride, oxide, or oxynitride on the substrate body 10 by sputtering, electron beam evaporation, or chemical vapor deposition.

Regarding the procedure for forming the first insulating layer 20 on the substrate body 10 by sputtering, for example, aluminum oxide (Al₂O₃) is used as a target. Since aluminum oxide (Al₂O₃) is an insulating material, the high frequency sputtering equipment may be used to form the sputtered film of aluminum oxide (Al₂O₃). The aluminum oxide (Al₂O₃) target is combined with an electrode. The substrate body 10 is disposed on an opposite electrode of the electrode. Aluminum oxide (Al₂O₃) particles are sputtered by discharging under reduced pressure in an atmosphere such as argon (Ar), hence aluminum oxide (Al₂O₃) is deposited on the substrate body 10.

Regarding the procedure for forming the first insulating layer 20 on the substrate body 10 by electron beam evaporation, for example, aluminum oxide (Al₂O₃) is used as a target. In electron beam evaporation, kinetic energy of the high-energy electron beam is converted into thermal energy for melting the target, and the target is coated at the saturated vapor pressure of the target that is close to the melting point. The evaporation rate of electron beam evaporation can be precisely controlled. Materials such as nitride, oxide, or oxynitride can be evaporated, and the substrate body 10 can grow a thin film without heating.

In addition, the thermal evaporation method is another applicable method that uses a thermal resistance heating method. A target (the material of the target is the same as the material of the first insulating layer 20) is directly in contact with a heating source (usually a tungsten boat). In comparison, the heat conversion efficiency of the electron beam evaporation method is better than the heat conversion efficiency of the thermal evaporation method.

Regarding the procedure for forming the first insulating layer 20 on the substrate body 10 by chemical vapor deposition, chemical vapor deposition is to expose the substrate body 10 to one or multiple different types of precursors. A chemical reaction and/or a chemical decomposition occur on a surface of the substrate body 10 to produce a thin film to be deposited. Different types of procedures are available for chemical vapor deposition, and an appropriate procedure can be selected according to different materials.

The present disclosure is not limited to the above-mentioned descriptions. For example, the first insulating layer 20 can also be formed by a sol-gel process. The sol-gel process is to uniformly disperse various ions of a precursor in a solvent on the surface of the substrate body 10. Then, the aluminum oxide (Al₂O₃) film is coated on the surface of the substrate body 10 by using a spin coating method, such that the film can be used as a buffer layer to flatten the surface of the substrate body 10.

In this embodiment, the thermal conductivity of the multi-layer composite heat dissipation substrate is further improved through the first insulating layer 20. Specifically, the material of the first insulating layer 20 in this embodiment has a thermal expansion coefficient similar to the thermal expansion coefficient of the substrate body 10. Therefore, the first insulating layer 20 can be well combined with the substrate body 10. In addition, the first insulating layer 20 has high thermal conductivity to conduct heat received by the electrode layer to the substrate body 10. On the other hand, the matching of the thermal expansion coefficient of the overall heat dissipation substrate and the thermal expansion coefficient (5×10\hat{ }(−6)/° C.) of the epitaxial layer is improved. For example, aluminum nitride is coated on the surface of the substrate body 10, such that the flatness and smoothness of the surface can be improved. Aluminum nitride (AlN) has high thermal conductivity (from 170 w/m·K to 230 w/m·K), and thermal expansion coefficient (from 3.5×10\hat{ }(−6)/° C. to 5.7×10\hat{ }(−6)/° C.) of aluminum nitride matches well with the epitaxial layer, silicon, or silicon carbide, etc., such that the first insulating layer 20 can be well combined with the substrate body 10 made of silicon carbide (SiC) and conduct heat to the substrate body 10. In addition, the thermal expansion coefficient of silicon nitride (Si₃N₄) is substantially 3.0×10\hat{ }(−6)/° C., which matches well with silicon (Si), silicon carbide (SiC), and other materials, and the thermal conductivity of silicon nitride (Si₃N₄) may reach 80 W/(m·K) to 100 W/(m·K). In addition, the specific heat, the thermal conductivity, and the thermal expansion coefficient of silicon oxynitride (SiOₓN_{y}) are close to those of silicon nitride (Si₃N₄). The specific heat, the thermal conductivity, and the thermal expansion coefficient of aluminum oxynitride (AlON) are close to those of aluminum nitride (AlN).

The first electrode layer 30 is formed on a surface of the first insulating layer 20. In this embodiment, the surface of the first insulating layer 20 is a top surface of the first insulating layer 20. The second electrode layer 40 is located below the substrate body 10. The first electrode layer 30 and the second electrode layer 40 both are a metal layer. In this embodiment, the second electrode layer 40 is formed on the second surface 12 of the substrate body 10. The first electrode layer 30 and the second electrode layer 40 are both composed of three interface metal compounds. For example, the first electrode layer 30 and the second electrode layer 40 can be composed of gold (Au)/nickel (Ni)/copper (Cu). The first electrode layer 30 is divided into a copper layer 33, a nickel layer 32, and a gold layer 31 in an order from the substrate body 10 toward the outside. The second electrode layer 40 is divided into a copper layer 43, a nickel layer 42, and a gold layer 41 in an order from the substrate body 10 toward the outside. However, the present disclosure is not limited thereto. The first electrode layer 30 and the second electrode layer 40 may be selected from the group consisting of gold (Au)/nickel (Ni)/copper (Cu), gold (Au)/palladium (Pd)/nickel (Ni)/copper (Cu), and gold (Au)/platinum (Pt)/titanium (Ti), but is not limited thereto. The first electrode layer 30 and the second electrode layer 40 may be formed by electroplating, sputtering, evaporation, or chemical vapor deposition.

The solder layer 50 is used to be electrically connected to a chip. The solder layer 50 is formed on a top surface of the first electrode layer 30. The solder layer 50 is composed of three interface metal compounds. For example, in this embodiment, the solder layer 50 is composed of gold (Au)/gold-tin (AuSn)/platinum (Pt). The solder layer 50 is divided into a platinum layer 53, a gold-tin layer 52, and a gold layer 51 in an order from the substrate body 10 toward the outside. However, the present disclosure is not limited thereto. The solder layer 50 may be selected from the group consisting of gold (Au)/gold-tin (AuSn)/platinum (Pt)/titanium (Ti), gold (Au)/gold-tin (AuSn)/platinum (Pt), and gold (Au)/gold-tin (AuSn), but is not limited thereto. The solder layer 50 may be formed by electroplating, sputtering, evaporation, or chemical vapor deposition.

### Second Embodiment

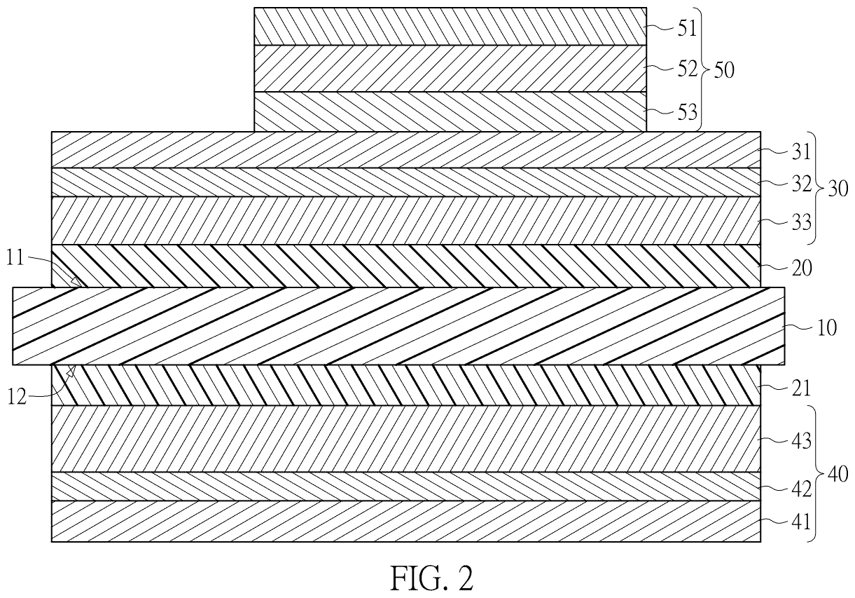

Referring to FIG. 2, in this embodiment, the multi-layer composite heat dissipation substrate includes a substrate body 10, a first insulating layer 20, a second insulating layer 21, a first electrode layer 30, a second electrode layer 40, and a solder layer 50.

This embodiment is similar to the first embodiment. A difference from the first embodiment is that, the multi-layer composite heat dissipation substrate in this embodiment further includes the second insulating layer 21. In this embodiment, the second insulating layer 21 is formed between the second surface 12 of the substrate body 10 and the second electrode layer 40.

The second insulating layer 21 is similar to the first insulating layer 20. The second insulating layer 21 may be formed by sputtering, electron beam evaporation, chemical vapor deposition, or sol-gel process. The second insulating layer 21 may be made of an insulating material selected from the group consisting of nitride, oxide, and oxynitride. The nitride may be, for example, silicon nitride (Si₃N₄) or aluminum nitride (AlN). The oxide may be, for example, silicon dioxide (SiO₂) or aluminum oxide (Al₂O₃). The oxynitride refers to a compound containing nitrogen, oxygen, and other elements, such as silicon oxynitride (SiOₓN_{y}) or aluminum oxynitride (AlON). In this embodiment, the thermal conductivity of the multi-layer composite heat dissipation substrate is further improved through the second insulating layer 21.

### BENEFICIAL EFFECTS OF THE EMBODIMENTS

Therefore, one of the beneficial effects of the present disclosure is that, by virtue of including the substrate body, the first insulating layer, the first electrode layer, the second electrode layer, and the solder layer, and the insulating layer being located between the substrate body and the electrode layer, the multi-layer composite heat dissipation substrate provided by the present disclosure has higher thermal conductivity compared with the thermal conductivity of the existing ceramic substrate, such that the heat dissipation effect for high-power chips is improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multi-layer composite heat dissipation substrate comprising:
a substrate body having a first surface and a second surface;
a first insulating layer formed on the first surface of the substrate body;
a first electrode layer formed on a top surface of the first insulating layer, wherein the first insulating layer is located between the substrate body and the first electrode layer;
a second electrode layer located below the substrate body; and
a solder layer formed on a top surface of the first electrode layer;
wherein the first insulating layer is made of an insulating material selected from the group consisting of nitride, oxide, and oxynitride.

2. The multi-layer composite heat dissipation substrate according to claim 1, wherein the substrate body is made of a material selected from the group consisting of electrically conductive silicon carbide, semi-insulating silicon carbide, ceramic, diamond-metal mixture, and diamond.

3. The multi-layer composite heat dissipation substrate according to claim 1, wherein the second electrode layer is formed on the second surface of the substrate body.

4. The multi-layer composite heat dissipation substrate according to claim 1, wherein the first insulating layer is formed by sputtering, electron beam evaporation, chemical vapor deposition, or sol-gel process.

5. The multi-layer composite heat dissipation substrate according to claim 1, further comprising a second insulating layer formed between the second surface of the substrate body and the second electrode layer, wherein the second insulating layer is made of an insulating material selected from the group consisting of nitride, oxide, and oxynitride.

6. The multi-layer composite heat dissipation substrate according to claim 5, wherein the second insulating layer is formed by sputtering, electron beam evaporation, chemical vapor deposition, or sol-gel process.

7. The multi-layer composite heat dissipation substrate according to claim 1, wherein the nitride is silicon nitride or aluminum nitride, the oxide is silicon dioxide or aluminum oxide, and the oxynitride is silicon oxynitride or aluminum oxynitride.

8. The multi-layer composite heat dissipation substrate according to claim 5, wherein the nitride is silicon nitride or aluminum nitride, the oxide is silicon dioxide or aluminum oxide, and the oxynitride is silicon oxynitride or aluminum oxynitride.

9. The multi-layer composite heat dissipation substrate according to claim 1, wherein the first electrode layer is selected from the group consisting of gold/nickel/copper, gold/palladium/nickel/copper, and gold/platinum/titanium, and the first electrode layer is formed by electroplating, sputtering, evaporation, or chemical vapor deposition.

10. The multi-layer composite heat dissipation substrate according to claim 3, wherein the second electrode layer is selected from the group consisting of gold/nickel/copper, gold/palladium/nickel/copper, and gold/platinum/titanium, and the second electrode layer is formed by electroplating, sputtering, evaporation, or chemical vapor deposition.

11. The multi-layer composite heat dissipation substrate according to claim 5, wherein the second electrode layer is selected from the group consisting of gold/nickel/copper, gold/palladium/nickel/copper, and gold/platinum/titanium, and the second electrode layer is formed by electroplating, sputtering, evaporation, or chemical vapor deposition.

12. The multi-layer composite heat dissipation substrate according to claim 1, wherein the solder layer is selected from the group consisting of gold/gold-tin/platinum/titanium, gold/gold-tin/platinum, and gold/gold-tin, and the solder layer is formed by electroplating, sputtering, evaporation, or chemical vapor deposition.
